(19) United States
(12) Patent Application Publication
(10) Pub. No.: US 2006/0156131 A1
(43) Pub. Date: Jul. 13, 2006

(54) Method of reducing hardware overhead upon generation of test pattern in built-in sef test

(75) Inventors: Sungho Kang, Seoul (KR); Dongsup Song, Seoul (KR)

Correspondence Address: Peter T. Kwon;G W i P S, Kangnam, P.O. Box 2301, Seoul, 135-242, KR

(73) Assignee: Yonsei University

(21) Appl. No.: 11/022,917

(22) Filed: Dec. 24, 2004

(51) Int. Cl. G01R 31/28

(52) U.S. Cl. 714/733

(57) ABSTRACT

A method of reducing hardware overhead upon the generation of a test pattern in a built-in self test is introduced, in which two pieces of hardware perform a lot of functions even prior to generation of deterministic patterns, thereby reducing the amount of hardware required for conventional pseudo-random pattern generation while not increasing test time appreciably. This method is characterized in that an LFSR is constructed such that it shifts only one bit among N−1 bits taken from the N bits of an N bit-pattern counter and bit counter to a scan chain.

### BACKGROUND OF THE INVENTION

1. Field of the Invention

The present invention relates to a method of minimizing hardware overhead upon the generation of a pseudo-random pattern in a built-in self test (BIST). More particularly, it has been carried out with the support of the Ministry of Information & Communication, Korea, under the Information Technology Research Center (ITRC) Support Program.

2. Related Prior Art

The various built-in self test (hereinafter, referred to as “BIST”) techniques can be classified as either a pseudo-random pattern generation technique or a deterministic pattern generation technique.

A Linear Feedback Shift Register (hereinafter, referred to as “LFSR”) architecture is most widely used for the pseudo-random pattern generation technique. Such a pseudo-random pattern generation technique is advantageous in eliminating the necessity of separate hardware aside from the LFSR architecture optimized for generation of such a pseudo-random pattern, but disadvantageous in not ensuring an increase in fault coverage up to a desired level. Most large-sized circuits do not achieve fault coverage of 100% with the generation of the pseudo-random pattern. A fault which has not been detected with the pseudo-random pattern generation is called a “hard-to-detect fault”. Assuming that an existing pseudo-random pattern generation technique employs a single scan chain, the LFSR generates pseudo-random patterns and continues to shift them by one pattern value to a scan chain. Accordingly, when the number of stages in the LFSR is n, a number of patterns equal to 2ⁿ−1 can be generated irrespective of the length of the scan chain.

As shown in FIG. 1, one example of additional hardware required for performing such pattern generation includes a bit counter. The design of the bit counter is determined depending on the length of the scan chain. That is, when the length of the scan chain is m, a bit counter having a length of log₂m is used. The bit counter is an essential constituent element which functions to provide the timing for when the patterns shifted to the scan chain will be applied to a circuit under test (also called “CUT”) after completing the shifting of the patterns to the scan chain in the case of a test-per-scan scheme. Also, the bit counter is a basic element for use in generation of pseudo-random patterns in the test-per-scan scheme along with the LFSR.

Besides the bit counter, a constituent element which can be used for generation of pseudo-random patterns includes a pattern counter which is required for signaling the time at which the pseudo-random pattern test will be terminated and controlling the generation of deterministic patterns. Dissimilar to the bit counter, the pattern counter serves as an index. That is, the pattern counter serves to increment a pattern value by one whenever pattern values are filled in the scan chain and the patterns are applied to the CUT.

As mentioned above, the bit counter and pattern counter are essential constituent elements required for performing the BIST. The bit counter for merely controlling the scan chain upon the generation of pseudo-random patterns and the pattern counter for merely performing control for a bit flipping function upon the generation of deterministic patterns do not play active roles in generating the pseudo-random patterns in spite of their advantageous dimension conditions. Therefore, it is required that the dimension conditions of both the bit counter and the pattern counter be sufficiently utilized even in the case of the pseudo-random test to thereby increase their efficiencies.

### SUMMARY OF THE INVENTION

Recently, a system-on-chip (SoC) architecture is being competitively developed in order to implement a very large scale integrated circuit (VLSI) chip having a high reliability within the shortest time period, meeting a desired specification, and at minimum cost by using an ultra-large scale integrated circuit fabrication technique. However, a test step for implementation of the VLSI contributes to a bottle-neck in terms of production cost, time, and reliability in the whole chip fabricating process. For this reason, the development of an effective test technique is very important economically and commercially. The criterion for evaluating the performance of the test technique includes fault coverage, test time, hardware overhead, etc. The novel test technique of the present invention is expected to attain fault coverage equivalent to that of an existing test technique, but with minimum hardware overhead and shorter test time as compared to the existing test technique, thereby effectively reducing production cost of semiconductors.

Therefore, it is an object of the present invention to provide a method of reducing hardware overhead upon the generation of a test pattern in a BIST, in which two pieces of hardware perform a lot of functions even prior to generation of deterministic patterns, thereby reducing the number of hardware items required for conventional pseudo-random pattern generation while not increasing test time appreciably.

To accomplish the above object, according to the present invention, there is provided a method of reducing hardware overhead upon the generation of a test pattern in a BIST by using a device for reducing hardware overhead upon the generation of test patterns in a BIST which tests a CUT using a scan chain, the device comprising an LFSR adapted to generate pseudo-random patterns and shift the generated pseudo-random patterns by one pattern value to the scan chain, a bit counter adapted to signal the time at which the pseudo-random patterns shifted to the scan chain will be applied to a CUT after the completion of the shifting of the pseudo-random patterns to the scan chain, and a pattern counter adapted to signal the time at which the pseudo-random pattern test will be terminated after generation of the pseudo-random patterns, wherein the LFSR shifts only one bit among N−1 bits taken from N bits of an N-bit pattern counter and bit counter to the scan chain.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a block diagram illustrating the principle of generating pseudo-random patterns according to the prior art.

FIG. 2 is a block diagram illustrating the principle of generating pseudo-random patterns according to the present invention.

FIG. 3 is a block diagram illustrating the principle of generating pseudo-random patterns which has been implemented simply according to one preferred embodiment of the present invention.

### DETAILED DESCRIPTION OF THE PREFERRED EMBODIMENT

Reference will now make in detail to the preferred embodiment of the present invention with reference to the attached drawings.

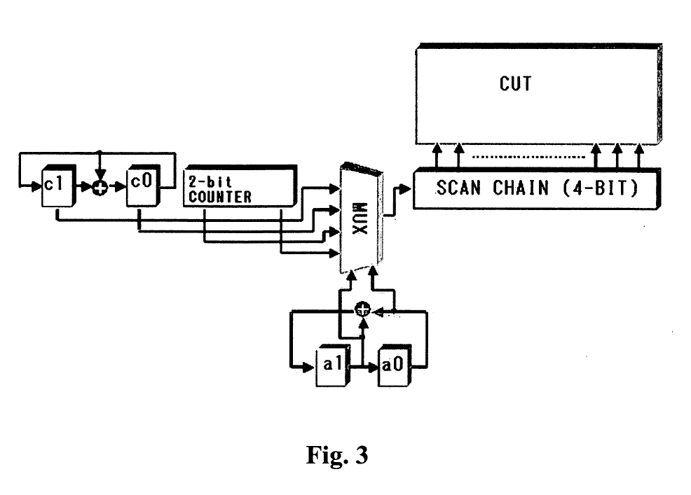

FIG. 2 illustrates the principle of generating pseudo-random patterns according to the present invention, and FIG. 3 illustrates the principle of generation of pseudo-random patterns which has been implemented simply according to one preferred embodiment of the present invention.

Referring to the drawings, in the inventive construction shown in FIG. 2, a 5-bit LFSR generates pseudo-random patterns such that it shifts only one bit among 31 bits taken from the total 32 bits of a 32 bit-pattern counter and bit counter to the scan chain. The reason why only 31 of the 32 total bits are sent to a multiplexer is that the number of different patterns which the 5-bit LFSR can generate is 2⁵−1 (=31), excepting a pattern in which all the bits are 0 or a pattern in which all the bits are 1.

In FIG. 2, each of the pattern counter and the bit counter may be configured either in the form of a typical counter or the form of an LFSR. In this case, it is assumed that the bit counter takes the form of a typical counter. The pattern counter takes the form of an LFSR since the case where the pattern counter and bit counter both take the form of a typical counter has a slightly lower fault coverage than the case where the pattern counter taker the form of an LFSR. Also, the pattern counter employs an LFSR in which an XOR gate is built, but not an LFSR in which each terminal of an XOR gate is positioned at the outside thereof. In the case where a bit value of the bit counter and the pattern counter in the 6-bit LFSR is selected, when any one bit value of 0 and 1 is too much or too little, the bit value selected by the LFSR is concentrated at either 0 or 1. As a result, since such pattern characteristics becomes a limiting factor in increasing the whole fault coverage within a short time, an LFSR of a type in which the number of bit values of 0 or 1 can be changed by several bit values is used rather than an LFSR of a type in which the number of bit values of 0 or 1 are changed by one bit value in one clock cycle.

This configuration uses a smaller number of bits as compared to a conventional one while maintaining fault coverage equivalent to or higher than that in the conventional configuration. The reason for this is that the functions of the bit counter and the pattern counter are enhanced during a pseudo-random pattern test prior to a deterministic pattern test.

Although the pattern counter performs the generation of the pseudo-random patterns, it has to able to act as a controller during the deterministic pattern test. Therefore, it is preferable not to directly change the bit value of the pattern counter upon the generation of the deterministic patterns. Since this is also applied to a conventional construction, there is of course no special limitation in a new construction.

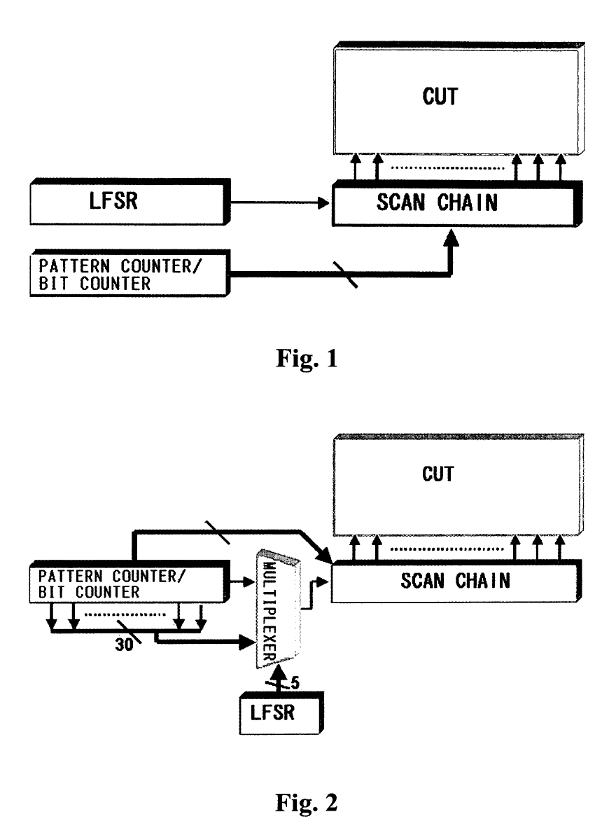

As shown in FIGS. 1 and 2, when the total number of bits of the bit counter is set to be identical to that of bits of the pattern counter, the length of the LFSR in FIG. 2 is shorter than that of the LFSR in FIG. 1. Assuming that the length of the LFSR is L in FIG. 2, the length of the LFSR shown in FIG. 1 becomes 2^{L}.

Consequently, the conventional construction of FIG. 1 has a test pattern generation length of 2^{m}−1 if 2^{L}=m, whereas the construction of FIG. 2 has a test pattern generation length of (m−1)×(2^{m}−1). Accordingly, it can be seen that the construction of FIG. 2 theoretically exhibits fault coverage not lower than that of FIG. 1 in a pseudo-random pattern test.

A simple example of this is shown in FIG. 3. A pattern generator shown in FIG. 3 and Table 1 is constructed so that it employs a 2-bit LFSR of an external XOR type, a 2-bit LFSR of an internal XOR type, a pattern counter, and a 2-bit counter as a bit counter, and the length of a scan chain is 4. In an actual case, when the length of the scan chain is h, the bit counter has a length corresponding to as many as log₂h bits, which is much shorter than the length of the scan chain. In this case, the total number of bits of the pattern counters and the bit counter is set to be identical to the length of the scan chain, and hence various patterns may not be generated from the scan chain unlike in the actual case. The generation cycle of patterns shown in Table 1 is equal to (4−1)×(2⁴−1)=45, i.e., an interval where after an initial vector (a₁a₀c₁c₀ [2 bit counter]) of 011100 the initial vector is repeated again.

TABLE 1

| | | | |
|---|---|---|---|
| a₁ | a₀ | c₁ | c₀ |

| | | | | | | | | | |
|---|---|---|---|---|---|---|---|---|---|
| 0 | 1 | 1 | 1 | 0 | 0 | X | x | X | x |
| 1 | 0 | 1 | 0 | 0 | 1 | 1 | x | X | x |
| 1 | 1 | 0 | 1 | 1 | 0 | 0 | 1 | X | x |
| 0 | 1 | 1 | 1 | 1 | 1 | 0 | 0 | 1 | x |
| 1 | 0 | 1 | 0 | 0 | 0 | 1 | 0 | 0 | 1 |
| 1 | 1 | 0 | 1 | 0 | 1 | 0 | 1 | 0 | 0 |
| 0 | 1 | 1 | 1 | 1 | 0 | 1 | 0 | 1 | 0 |
| 1 | 0 | 1 | 0 | 1 | 1 | 1 | 1 | 0 | 1 |
| 1 | 1 | 0 | 1 | 0 | 0 | 1 | 1 | 1 | 0 |
| 0 | 1 | 1 | 1 | 0 | 1 | 0 | 1 | 1 | 1 |
| 1 | 0 | 1 | 0 | 1 | 0 | 1 | 0 | 1 | 1 |
| . | . | . | . | . | . | . | . | . | . |
| . | . | . | . | . | . | . | . | . | . |
| . | . | . | . | . | . | . | . | . | . |

The experimental result for verification of a pattern generation method proposed by the preset invention using several benchmark circuits will now be described hereinafter.

Table 2 below is divided into four sections in which the first and second sections are control groups. The first section shows a result of using an existing 32-bit LFSR, and the second section shows a result of using a pattern generator of a size requiring the same hardware as that in the third and fourth sections. In the third section, the bit counter is implemented in the form of an LFSR, and in the fourth section, the bit counter is implemented in the form of a counter. The third and fourth section all show the results of the use of a 5-bit LFSR.

TABLE 2

| | 32-bit LFSR | | 12-bit LFSR | | | | | |
|---|---|---|---|---|---|---|---|---|
| | (prior art) | | (prior art) | | 5-bit LFSR (LFSR) | | 5-bit LFSR(counter) | |
| | Remaining | | Remaining | | Remaining | | Remaining | |
| | Fault | Fault | Fault | Fault | Fault | Fault | Fault | Fault |
| Circuits | number | coverage | number | coverage | number | coverage | number | coverage |
| s208 | 5 | 97.67 | 5 | 97.67 | 4 | 98.14 | 3 | 98.60 |
| s344 | 0 | 100.00 | 0 | 100.00 | 0 | 100.00 | 0 | 100.00 |
| s349 | 2 | 99.43 | 2 | 99.43 | 2 | 99.43 | 2 | 99.43 |
| s382 | 0 | 100.00 | 0 | 100.00 | 0 | 100.00 | 0 | 100.00 |
| s386 | 1 | 99.74 | 36 | 90.62 | 2 | 99.48 | 12 | 96.88 |
| s400 | 6 | 98.58 | 6 | 98.58 | 6 | 98.58 | 6 | 98.58 |
| s420 | 44 | 89.77 | 67 | 84.42 | 33 | 92.33 | 35 | 91.86 |
| s444 | 14 | 97.05 | 14 | 97.05 | 14 | 97.05 | 14 | 97.05 |
| s510 | 0 | 100.00 | 0 | 100.00 | 0 | 100.00 | 0 | 100.00 |
| s526 | 16 | 97.12 | 13 | 97.66 | 15 | 97.30 | 18 | 96.76 |
| s641 | 12 | 97.43 | 19 | 95.93 | 22 | 95.29 | 20 | 95.72 |
| s1196 | 57 | 95.41 | 52 | 95.81 | 72 | 94.20 | 51 | 95.89 |
| s1238 | 134 | 90.11 | 126 | 90.70 | 132 | 90.26 | 129 | 90.48 |
| s1423 | 50 | 96.70 | 162 | 89.31 | 26 | 98.28 | 26 | 98.28 |
| s1488 | 14 | 99.06 | 28 | 98.12 | 27 | 98.18 | 24 | 98.38 |
| s1494 | 26 | 98.27 | 41 | 97.28 | 33 | 97.81 | 36 | 97.61 |
| s5378 | 158 | 96.57 | 146 | 96.83 | 131 | 97.15 | 134 | 97.09 |
| S13207 | 857 | 91.27 | 2562 | 73.90 | 444 | 95.48 | 602 | 93.87 |
| S15850 | 1025 | 91.26 | 1958 | 83.30 | 1034 | 91.18 | 1121 | 90.44 |
| S38417 | 2156 | 93.09 | 4526 | 85.48 | 2424 | 92.23 | 2043 | 93.45 |
| S38584 | 2028 | 94.41 | 2613 | 92.80 | 1946 | 94.64 | 1922 | 94.71 |

Each section of Table 2 consists of remaining fault number and fault coverage, which exhibit the number of faults detected out of all possible faults and the fault coverage of a pseudo-random pattern test. It can be seen from Table 2 that the use of a 5-bit LFSR is on average similar to or somewhat superior to that of the other prior art 32- and 12-bit LFSRs in fault coverage. In addition, it can be seen that in the existing method using the 12-bit LFSR, fault coverage is remarkably low for larger-scale circuits. Accordingly, it can be seen from the experimental results that a novel method using the 5-bit LFSR requires a smaller amount of hardware as compared to a conventional method using much larger hardware while exhibiting fault coverage similar to or much higher than that of the conventional method in a pseudo-random pattern test. Theoretically, it is preferable to use an LFSR previously optimized in terms of performance in the pseudo-random pattern test. However, since there is additional hardware needed for the pseudo-random pattern test, such hardware is used to generate the patterns, which results in generation of patterns with the same performance as that in the conventional method in spite of the use of smaller hardware.

Table 3 shows the CPU time spent for testing the patterns using a small-sized LFSR. In Table 3, the test time is verified as another item for the performance evaluation in addition to fault coverage. It can be seen from Table 3 that the inventive method using a 5-bit LFSR does not require more patterns as compared to the existing method, thereby proving higher efficiency of the novel construction. In Table 3, the 12-bit LFSR of the conventional method in Table 2 is excluded. The aim for this is to compare the number of patterns used for obtaining fault coverage between the 32-bit LFSR of the conventional method using much larger-scale hardware than in the 12-bit LFSR and the 5-bit LFSR of the newly proposed method to prove randomization of patterns generated by the inventive method in Table 3, since Table 2 exhibited that the inventive method is superior to the conventional method using the 12-bit LFSR.

TABLE 3

| | 32-bit LFSR (prior art) | | | 5-bit LFSR (LFSR) | | | 5-bit LFSR(counter) | | |
|---|---|---|---|---|---|---|---|---|---|
| | Remaining | | Total | Remaining | | Total | Remaining | | Total |
| | Fault | Fault | pattern | Fault | Fault | pattern | Fault | Fault | pattern |
| Circuits | number | coverage | number | number | coverage | number | number | coverage | number |
| s208 | 5 | 97.67 | 24320 | 4 | 98.14 | 29792 | 3 | 98.60 | 21888 |
| s344 | 0 | 100.00 | 6144 | 0 | 100.00 | 8448 | 0 | 100.00 | 3072 |
| s349 | 2 | 99.43 | 26112 | 2 | 99.43 | 26880 | 2 | 99.43 | 26880 |
| s382 | 0 | 100.00 | 10752 | 0 | 100.00 | 10752 | 0 | 100.00 | 10752 |
| s386 | 1 | 99.74 | 42848 | 2 | 99.48 | 20384 | 12 | 96.88 | 20800 |
| s400 | 6 | 98.58 | 30720 | 6 | 98.58 | 28416 | 6 | 98.58 | 26880 |
| s420 | 44 | 89.77 | 77280 | 33 | 92.33 | 43680 | 35 | 91.86 | 84000 |
| s444 | 14 | 97.05 | 37632 | 14 | 97.05 | 33024 | 14 | 97.05 | 28416 |
| s510 | 0 | 100.00 | 16800 | 0 | 100.00 | 19200 | 0 | 100.00 | 17600 |
| s526 | 16 | 97.12 | 39936 | 15 | 97.30 | 36864 | 18 | 96.76 | 34560 |
| s641 | 12 | 97.43 | 86400 | 22 | 95.29 | 74304 | 20 | 95.72 | 69120 |
| s1196 | 57 | 95.41 | 98304 | 72 | 94.20 | 89088 | 51 | 95.89 | 94208 |
| s1238 | 134 | 90.11 | 98304 | 132 | 90.26 | 125952 | 129 | 90.48 | 97280 |
| s1423 | 50 | 96.70 | 131040 | 26 | 98.28 | 224224 | 26 | 98.28 | 206752 |
| s1488 | 14 | 99.06 | 30016 | 27 | 98.18 | 26880 | 24 | 98.38 | 26432 |
| s1494 | 26 | 98.27 | 30016 | 33 | 97.81 | 27776 | 36 | 97.61 | 26432 |
| s5378 | 158 | 96.57 | 540992 | 131 | 97.15 | 979264 | 134 | 97.09 | 862848 |
| s13207 | 857 | 91.27 | 6496000 | 444 | 95.48 | 10841600 | 602 | 93.87 | 8220800 |
| s15850 | 1025 | 91.26 | 5474560 | 1034 | 91.18 | 3284736 | 1121 | 90.44 | 2502656 |
| s38417 | 2156 | 93.09 | 19701760 | 2424 | 92.23 | 28434432 | 2043 | 93.45 | 21512192 |
| s38584 | 2028 | 94.41 | 13773312 | 1946 | 94.64 | 18270720 | 1922 | 94.71 | 14241792 |

As described above, according to the present invention, the novel test technique of the present invention is expected to attain fault coverage equivalent to that of an existing test technique but with minimum hardware overhead and shorter test time as compared to the existing test technique, thereby effectively reducing production cost of semiconductors.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A method of reducing hardware overhead upon the generation of a test pattern in a BIST by using a device for reducing hardware overhead upon the generation of test patterns in a BIST which tests a CUT using a scan chain, the device comprising:
an LFSR adapted to generate the test patterns and to shift the generated test patterns by one pattern value to the scan chain,
a bit counter adapted to signal the time at which the test patterns shifted to the scan chain will be applied to a CUT after the completion of the shifting of the test patterns to the scan chain, and
a pattern counter adapted to signal the time at which the test pattern test will be terminated after generation of the test patterns, wherein the LFSR shifts only one bit among N−1 bits taken from N bits of an N bit-pattern counter and bit counter to the scan chain.

2. The method according to claim 1, wherein the LFSR shifts only one bit among N−1 bits taken from N bits of an N bit-pattern counter and bit counter to the scan chain by using a multiplexer.

3. The method according to claim 1, wherein each of the bit counter and the pattern counter is in the form of a typical counter.

4. The method according to claim 1, wherein each of the bit counter and the pattern counter is in the form of an LFSR.

5. The method according to claim 4, wherein the pattern counter is in the form of an LFSR in which an XOR gate is built.

6. A device for reducing hardware overhead upon the generation of test patterns in a BIST which tests a CUT using a scan chain, the device comprising:
an LFSR adapted to generate pseudo-random patterns and to shift the generated pseudo-random patterns by one pattern value to the scan chain;
a bit counter adapted to signal the time at which the pseudo-random patterns shifted to the scan chain will be applied to a CUT after the completion of the shifting of the pseudo-random patterns to the scan chain; and
a pattern counter adapted to signal the time at which the pseudo-random pattern test will be terminated after generation of the pseudo-random patterns, wherein the LFSR shifts only one bit among N−1 bits taken from the N bits of an N bit-pattern counter and bit counter to the scan chain.

7. The device according to claim 6, further comprising a multiplexer adapted to allow the LFSR to shift only one bit among N−1 bits taken from the N bits of an N bit-pattern counter and bit counter to the scan chain.

8. The device according to claim 6, wherein each of the bit counter and the pattern counter is in the form of a typical counter.

9. The device according to claim 6, wherein each of the bit counter and the pattern counter is in the form of an LFSR.

10. The device according to claim 9, wherein the pattern counter is in the form of an LFSR in which an XOR gate is built.
